(19) United States
(12) Patent Application Publication
(10) Pub. No.: US 2025/0349633 A1
(43) Pub. Date: Nov. 13, 2025

(54) SEMICONDUCTOR DEVICE WITH HEAT SINK

(71) Applicant: SILICONWARE PRECISION INDUSTRIES CO., LTD., Taichung City (TW)

(72) Inventors: Jia-Huei HUNG, Taichung City (TW); Cheng-Sheng HSU, Taichung City (TW); Li-Hui PENG, Taichung City (TW)

(21) Appl. No.: 18/819,611

(22) Filed: Aug. 29, 2024

(30) Foreign Application Priority Data
May 7, 2024 (TW) 113116876

(51) Int. Cl. H01L 23/10; H01L 23/00; H01L 23/367

(52) U.S. Cl. CPC H01L 23/10; H01L 23/3675; H01L 24/16; H01L 24/32; H01L 24/33; H01L 24/73; H01L 2224/16221; H01L 2224/32221; H01L 2224/33181; H01L 2224/73204

(57) ABSTRACT

A semiconductor device with a heat sink is provided, in which a base material is rectangular and provided with heat sink mounting areas at four sides of the base material. An adhesive layer is disposed on the heat sink mounting areas, and the adhesive layer at at least one side forms a first pattern, where a width of the first pattern is tapered from both ends of the side toward a center of the side, and the heat sink is mounted on the base material via the adhesive layer.

### CROSS-REFERENCE TO RELATED APPLICATIONS

The present application is based upon and claims the right of priority to TW Patent Application No. 113116876, filed May 7, 2024, the disclosure of which is hereby incorporated by reference herein in its entirety for all purposes.

### BACKGROUND

### 1. Technical Field

The present disclosure relates to a semiconductor device, and more particularly, to a semiconductor device with a heat sink.

### 2. Description of Related Art

Flip Chip Ball Grid Array (FCBGA) semiconductor package is a package that has both a flip chip and a ball grid array. At least one chip is electrically connected to one surface of the substrate via a plurality of solder bumps, and a plurality of solder balls serving as input/output (I/O) terminals are placed on the other surface of the substrate.

In order to dissipate the heat generated by the operation of the chip, the above-mentioned semiconductor package is provided with a heat sink. The heat sink can be bonded to the substrate via adhesive, and the area of the heat sink is often larger than the chip area, so that the heat sink can cover and be bonded to the chip, thereby effectively dissipating the heat from the chip.

However, to improve the operating performance of the semiconductor package, passive components are disposed on the substrate, which reduces the area available for the heat sink on the substrate, making it difficult for the heat sink to firmly be attached to and positioned on the substrate. This may cause the heat sink to fall off, especially if a large heat sink is used. In addition, if the substrate with the heat sink is subjected to external forces such as vibration or collision, the heat sink may fall off; or, the structure of the adhesive and other adhesives that bond the heat sink to the substrate may be easily damaged by stress, so delamination may occur between the heat sink and the substrate, causing the heat sink to fall off.

Therefore, how to solve the above problems without changing the structure of the heat sink itself (for example, it would not solve the requirement of the end customer for the semiconductor package to be placed in the end product if the shape or size of the heat sink is changed) is an urgent need in the industry.

### SUMMARY

In view of the aforementioned shortcomings of the prior art, the present disclosure provides a semiconductor device, which comprises: a base material provided with heat sink mounting areas at sides of the base material; an adhesive layer disposed on the heat sink mounting areas, wherein the adhesive layer at at least one side forms a first pattern, and a width of the first pattern is tapered from two ends of the side toward a center of the side; and a heat sink mounted on the base material via the adhesive layer.

In the aforementioned semiconductor device, the base material is a carrier or a package module.

In the aforementioned semiconductor device, the base material is bonded with an electronic component.

In the aforementioned semiconductor device, the first pattern has a strip-stepped shape, and a width of the strip-stepped shape is tapered from the two ends of the side toward the center of the side in a multiple-stage manner. Alternatively, a shape of the first pattern is tapered from the two ends of the side toward the center of the side to represent a trapezoid or a triangle.

In the aforementioned semiconductor device, the adhesive layer at another side opposing to the side forms a second pattern. The second pattern has a strip-stepped shape. A width of the second pattern is tapered from two ends of the another side toward a center of the another side. Alternatively, a shape of the second pattern is tapered from the two ends of the another side toward the center of the another side to represent a trapezoid or a triangle.

In the aforementioned semiconductor device, the adhesive layer at two opposite sides adjacent to the side and the another side form a third pattern and a fourth pattern, and the third pattern and the fourth pattern are striped rectangles.

In the aforementioned semiconductor device, the heat sink includes a heat dissipation sheet and a support portion connected to the heat dissipation sheet, and the support portion is erected on the base material via the adhesive layer.

As can be seen from the above, the semiconductor device of the present disclosure is characterized in that the adhesive layer at at least one side of the base material forms a first pattern. A width of the first pattern is tapered from two ends of the side toward a center of the side, and further forms a strip-stepped shape that is tapered inward. In addition, an another pattern at another side opposing the side also has a strip-stepped shape that is tapered inward. Thus, the stress can be effectively reduced and the reliability can be effectively improved, and the use amount of the adhesive layer is reduced to save cost.

Therefore, compared to the prior art, the structure of the semiconductor device of the present disclosure does not require the addition of new development processes and materials or the purchase of machines. It can solve the existing technical problems in the industry by adding simple steps to the existing machines, without a large amount of additional cost and without changing the shape or size of the heat sink, so as to meet the end product requirements of the end customers.

### BRIEF DESCRIPTION OF THE DRAWINGS

FIG. 1 is a schematic cross-sectional view of a semiconductor device with a heat sink according to the present disclosure.

FIG. 2 is a schematic local plane view of the semiconductor device with the heat sink according to the present disclosure.

### DETAILED DESCRIPTION

Embodiments of the present disclosure are described below by specific examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

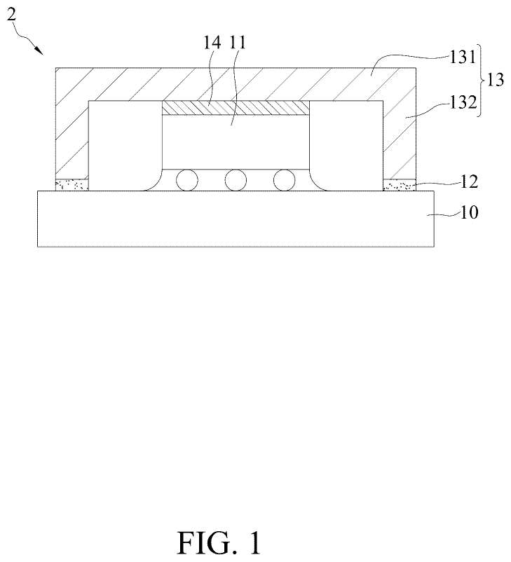

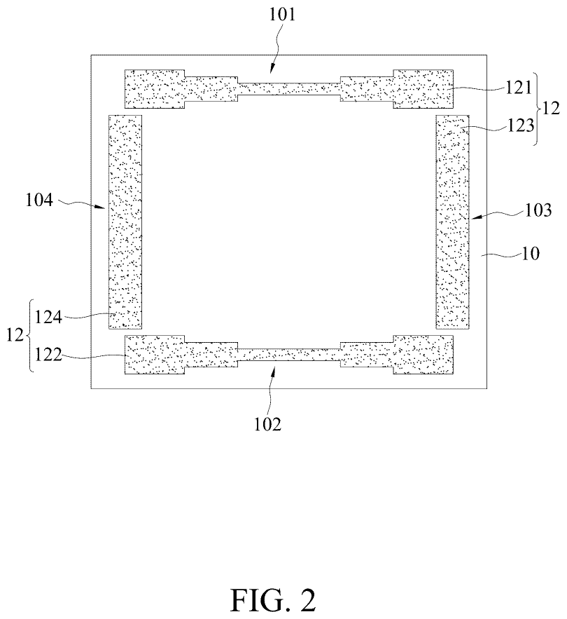

FIG. 1 and FIG. 2 are a schematic cross-sectional view and a schematic local plane view, respectively, of a semiconductor device 2 with a heat sink according to the present disclosure.

As shown in FIG. 1 and FIG. 2, a base material 10, which is rectangular and provided with heat sink mounting areas, is provided. The heat sink mounting areas are provided at four sides of the base material 10, and the base material 10 is bonded with an electronic component 11. In an embodiment, the base material 10 may be a carrier such as a packaging substrate having a core layer and a circuit structure, or a coreless circuit structure; and in the carrier, a circuit layer is formed on a dielectric material, such as the redistribution layer (RDL). The carrier can also be other carrier structures capable of carrying electronic components such as chips, for example, the carrier can be a lead frame or a silicon interposer, and the present disclosure is not limited to as such. In another embodiment, the base material 10 can be a package module including a circuit layer, an electronic component, and an encapsulation layer covering the electronic component. In an embodiment and in the drawings, it is described that the base material 10 is a carrier.

In an embodiment, the base material 10 has rectangular shape, such as is in the shape of a rectangle or square. At least one electronic component 11 is disposed at a portion of the region near the center of the base material 10. The electronic component 11 is, for example, an active component, a passive component, or a combination of the active component and the passive component. The active component is a semiconductor chip, and the passive component is a resistor, a capacitor, or an inductor.

Each of the four sides of the base material 10 is provided with a heat sink mounting area for mounting a heat sink 13, which helps to dissipate the thermal energy generated by the electronic component 11, such as an active component, a passive component, or a combination of the active component and the passive component, on the base material 10 during operation.

An adhesive layer 12 is formed on the heat sink mounting areas of the base material 10, so that the heat sink 13 can be bonded onto the base material 10 via the adhesive layer 12. In an embodiment, the adhesive layer 12 is formed onto the heat sink mounting areas by dispensing adhesive, and the adhesive layer 12 at at least one side (i.e., a first side 101) forms a first pattern 121. A width of the first pattern 121 is tapered from both ends of the side to the center of the side. For example, the adhesive layer 12 is made of non-conductive adhesive.

Furthermore, the adhesive layer 12 at the first side 101 of the base material 10 forms the first pattern 121, and the width of the first pattern 121 is tapered from both ends of the first side 101 to the center of the first side 101. Unlike the conventional industry where the adhesive dispensing pattern on the substrate is rectangular on all four sides, which may cause problems such as the heat sink falling off the substrate in a case of an uneven stress, the width of the first pattern 121 on the base material 10 of the present disclosure is tapered from both ends to the center. Accordingly, the stress generated by the adhesive layer 12 after being subjected to cold and heat cycles can be effectively reduced (the stress generated during the process is mainly concentrated at the side), thereby reducing the use of the adhesive layer 12 and saving the manufacturing cost of the entire semiconductor device 2.

In an embodiment, the first pattern 121 has a strip-stepped shape, and a width of the strip-stepped shape is tapered from both ends of the first side 101 to the center of the first side 101 in a multiple-stage manner. For example, the width of the strip-stepped shape is tapered in three stages from both ends of the first side 101 to the center of the first side 101. In addition, the width of the strip-stepped shape may also be tapered in four or five stages from both ends of the first side 101 to the center of the first side 101. In another embodiment, the shape of the first pattern 121 may also be tapered from both ends of the first side 101 to the center of the first side 101 to represent a trapezoid or a triangle. The shape of the first pattern 121 may be correspondingly adjusted based on the heat dissipation concentration generated by the electronic component on the base material 10.

In an embodiment, the patterns (i.e., a third pattern 123 and a fourth pattern 124) formed by the adhesive layer 12 at two opposite sides (i.e., a third side 103 and a fourth side 104) adjacent to the first side 101 may have a shape of a striped rectangle. In addition, the pattern (i.e., a second pattern 122) formed by the adhesive layer 12 at the another side (i.e., a second side 102) opposing the first side 101 can be the same as the pattern (i.e., the first pattern 121) at the first side 101, for example, the width of a strip-stepped shape is tapered in three stages from both ends of the second side 102 to the center of the second side 102. In addition, the width of the strip-stepped shape may also be tapered in four or five stages from both ends of the second side 102 to the center of the second side 102. In another embodiment, the shape of the second pattern 122 may also be tapered in a trapezoidal or triangular manner from both ends of the second side 102 to the center of the second side 102. The shape of the second pattern 122 may be correspondingly adjusted based on the heat dissipation concentration generated by the electronic component on the base material 10. In other words, the width of the shape of the first pattern 121 can be the same as or different from the width of the shape of the second pattern 122.

In an embodiment, the heat sink 13 includes a heat dissipation sheet 131 and a support portion 132 connected to the heat dissipation sheet 131, wherein the support portion 132 is erected on the base material 10 via the adhesive layer 12, and the heat dissipation sheet 131 is connected onto the electronic component 11 via a thermal interface material (TIM) 14 to effectively dissipate the heat generated when the electronic component 11 operates.

Therefore, the semiconductor device 2 provided by the present disclosure is mainly provided with the patterned adhesive layer 12 at the sides of the base material 10, wherein the width of the first pattern formed by the adhesive layer 12 at at least one side (where the stress is maximum) is tapered from two ends of the side toward the center of the side, thereby reducing the amount of adhesive to reduce the stress. In addition, the structure of the semiconductor device 2 does not require the addition of new development processes and materials or the purchase of machines, and can solve the existing technical problems in the industry by adding simple steps to the existing machine. Therefore, there is no large additional cost, and no change in the shape or size of the heat sink, so as to meet the end product requirements of end customers.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A semiconductor device, comprising:
a base material provided with heat sink mounting areas at sides of the base material;
an adhesive layer disposed on the heat sink mounting areas, wherein the adhesive layer at a first side of the base material forms a first pattern, and a width of the first pattern is tapered from two ends of the first side toward a center of the first side; and
a heat sink mounted on the base material via the adhesive layer.

2. The semiconductor device of claim 1, wherein the base material is a carrier or a package module.

3. The semiconductor device of claim 1, wherein the base material is bonded with an electronic component.

4. The semiconductor device of claim 1, wherein the first pattern has a strip-stepped shape, and a width of the strip-stepped shape is tapered from the two ends of the first side toward the center of the first side in a multiple-stage manner.

5. The semiconductor device of claim 1, wherein a shape of the first pattern is tapered from the two ends of the first side toward the center of the first side to represent a trapezoid or a triangle.

6. The semiconductor device of claim 1, wherein the adhesive layer at a second side of the base material forms a second pattern, the second side opposes the first side, and a width of the second pattern is tapered from two ends of the second side toward a center of the second side.

7. The semiconductor device of claim 6, wherein the second pattern has a strip-stepped shape, and a width of the strip-stepped shape is tapered from the two ends of the second side toward the center of the second side in a multiple-stage manner.

8. The semiconductor device of claim 6, wherein a shape of the second pattern is tapered from the two ends of the second side toward the center of the second side to represent a trapezoid or a triangle.

9. The semiconductor device of claim 6, wherein the adhesive layer at a third side of the base material forms a third pattern, the third side is adjacent to the first side and the second side, and the third pattern is striped rectangle.

10. The semiconductor device of claim 6, wherein the adhesive layer at a fourth side of the base material forms a fourth pattern, the fourth side opposes the third side and is adjacent to the first side and the second side, and the fourth pattern is striped rectangle.

11. The semiconductor device of claim 1, wherein the heat sink includes a heat dissipation sheet and a support portion connected to the heat dissipation sheet, and the support portion is erected on the base material via the adhesive layer.
